(19) United States
(12) Patent Application Publication
(10) Pub. No.: US 2009/0057706 A1
(43) Pub. Date: Mar. 5, 2009

(54) SET OF OHMIC CONTACT ELECTRODES ON BOTH P-TYPE AND N-TYPE LAYERS FOR GAN-BASED LED AND METHOD FOR FABRICATING THE SAME

(76) Inventors: Philip Chan, Guangzhou (CN); Raymond Wang, Guangzhou (CN); Leo Lei, Guangzhou (CN)

Correspondence Address: RADER, FISHMAN & GRAUER PLLC, 39533 WOODWARD AVENUE, SUITE 140, BLOOMFIELD HILLS, MI, 48304-0610, US

(21) Appl. No.: 12/184,172

(22) Filed: Jul. 31, 2008

(30) Foreign Application Priority Data
Sep. 4, 2007 (CN) 200710146312.3

(51) Int. Cl. H01L 33/00

(52) U.S. Cl. 257/99; 438/46; 257/E33.064

(57) ABSTRACT

The present disclosure relates to set of a ohmic contact electrodes on both P-type and N-type layers of a GaN-based light emitting diode (LED) and a fabricating method thereof. The materials of ohmic contact electrodes on both P-type and N-type layers of a GaN-based LED are a metal combination of Cr/Pd/Au. In one embodiment, the fabricating method comprises etching out an N-type GaN layer on an epitaxial structure on a sapphire substrate, and evaporating a P-type transparent electrode layer on the P-type GaN layer, then positioning patterns of the ohmic contact electrodes on both P-type and N-type layers, and then evaporating a metal combination of a Cr layer 50 Å to 500 Å thick, a Pd layer 300 Å to 1000 Å thick and an Au layer 3000 Å to 20000 Å thick in turn on the P-type transparent electrode layer and N-type GaN layer respectively, and then annealing electrodes of the chip, on which the Cr, Pd and Au layers are evaporated in nitrogen atmosphere for 5 minutes to 20 minutes at a temperature from 200 degrees to 450 degrees. Excellent ohmic contact characteristics and better thermal stability are obtained as well as higher oxidation resistance, thus improving the reliability of diode.

### CROSS-REFERENCE TO RELATED APPLICATIONS

This application claims priority from Chinese Patent Application Serial No. 200710146312.3 filed Sep. 4, 2006, the disclosure of which, including the specification, drawings and claims, is incorporated herein by reference in its entirety.

### TECHNICAL FIELD

The present disclosure pertains to the field of semiconductor technology, and more particularly, relates to a set of ohmic contact electrodes on both P-type and N-type layers of a GaN-Based light emitting diode (LED) and the fabricating method thereof.

### BACKGROUND ART

Generally speaking, the contact behavior between metal and a semiconductor comprises ohmic contact and Schottky Contact. As to ohmic contact, the current-voltage relation on the contact interface shows linear characteristics, and compared with the resistance value of semiconductor itself, the contact resistance value between metal and semiconductor is almost negligible.

At present, the popular materials for fabricating P-type ohmic contact electrodes and N-type ohmic contact electrodes are metal combinations of Ti/Al, Cr/Pt/Au. The metal electrode fabricated by this kind of metal combination has lower characteristic contact impedance, thus creating excellent ohmic contact. However, the metal electrode fabricated by this kind of metal combination has poor thermal stability, thus resulting in low reliability of the diode.

### SUMMARY

In view of the issues described above, some of the objectives of the present disclosure are to provide set of ohmic contact electrodes on both P-type and N-type layers of a GaN-Based LED and the fabricating method thereof. By choosing metals which have an appropriate work function, there are achieved not only excellent ohmic contact on the interface of metal and semiconductor, but also better thermal stability and oxidation resistance, therefore the reliability of diode is improved entirely.

To achieve the above aims, there is provided a set of ohmic contact electrodes on both P-type and N-type layers of GaN-Based LED, wherein the material of ohmic contact electrode is the metal combination of Cr/Pd/Au. The first layer of the ohmic contact electrode is evaporated on the P-type transparent electrode layer. The N—GaN layer is Cr, the second layer is Pd, and the third layer is Au. The thickness of the Cr layer is equal to or thicker than 50 Å and equal to or thinner than 500 Å. The thickness of the Pd layer is equal to or thicker than 300 Å and equal to or thinner than 1000 Å. The thickness of the Au layer is equal to or thicker than 3000 Å and equal to or thinner than 20000 Å.

There is also provided a method for fabricating a set of ohmic contact electrodes on both P-type and N-type layers of a GaN-based LED. The method comprises the following steps:
(1) epitaxially growing an N-type GaN layer, an active luminescent layer, and a P-type GaN layer on a sapphire substrate;
(2) etching out part of said N-type GaN layer;
(3) evaporating a P-type transparent electrode layer on the surface of the P-type GaN layer at a vacuum degree of less than 1×10⁻⁶ Torr, and then removing appropriate part of P-type transparent electrode layer by photolithography and etching;
(4) coating a photoresister on the surface of an epitaxial structure of a chip, photolithographing and developing both P-type transparent electrode layers and N-type GaN layers to position patterns of ohmic contact electrodes on the P-type and N-type layers respectively;
(5) evaporating a metal combination of Cr, Pd and Au in turn on the P-type transparent electrode layer and N-type GaN layer respectively at a vacuum degree of less than 1×10⁻⁶ Torr, and then removing unnecessary photoresisters and metals after the evaporation is finished;
(6) annealing electrodes of the chip, on which Cr, Pd and Au are evaporated, in nitrogen atmosphere for a time being equal to or longer than 5 minutes and equal to or shorter than 20 minutes at a temperature being equal to or higher than 2000 and equal to or lower than 4500 to form ohmic contact electrodes on both P-type and N-type layers.

By using the metal combination of Cr/Pd/Au as the material for the ohmic contact electrodes, the present disclosure can obtain excellent ohmic contact characteristics. Moreover, compared with existing technology, the present disclosure has following advantages:

First, the more effective potential barrier layer of Pd prevents Au from diffusing to the surface of N—GaN during heat treatment to prevent deterioration of electrical properties. Second, during heat treatment, Pd diffuses downward toward the N—GaN to increase the electron concentration on the surface of the N—GaN, thus making the fabrication of the ohmic contact more easily; and the third, better thermal stability can be obtained and the electrode is not easy to be oxidized, thereby the reliability of the diode is improved.

### BRIEF DESCRIPTION OF THE DRAWINGS

The accompanying drawings, which are incorporated in and constitute a part of specification, illustrate an exemplary embodiment of the present invention and, together with the general description given above and the detailed description of the preferred embodiment given below, serve to explain the principles of the present invention.

FIG. 1 is a fabrication flow chat of set of ohmic contact electrodes on both P-type and N-type layers of GaN-based LED;

FIG. 2 is a sectional view of the epitaxial structure of a GaN-based LED chip on a sapphire substrate;

FIG. 3 is a schematic view illustrating etching out part of an N-type layer on the epitaxial structure of chip and forming a P-type transparent electrode layer;

FIG. 4 is a schematic view showing positioning of ohmic contact electrodes on both P-type and N-type layers which are to be evaporated;

FIG. 5 is a structure scheme of ohmic contact electrodes on both P-type and N-type layers of GaN-based LED fabricated by using a metal combination of Cr/Pd/Au;

FIG. 6 is a relation curve between current and voltage (I-V) obtained by testing ohmic contact electrodes on both P-type and N-type layers of GaN-based LED in a first embodiment;

FIG. 7 is a relation curve between current and voltage (I-V) obtained by testing ohmic contact electrodes on both P-type and N-type layers of GaN-based LED in a second embodiment;

FIG. 8 is a relation curve between current and voltage (I-V) obtained by testing ohmic contact electrodes on both P-type and N-type layers of GaN-based LED in a third embodiment;

FIG. 9 is a relation curve between current and voltage (I-V) obtained by testing ohmic contact electrodes on both P-type and N-type layers of GaN-based LED in a fourth embodiment;

FIG. 10 is a relation curve between current and voltage (I-V) obtained by testing ohmic contact electrodes on both P-type and N-type layers of GaN-based LED in a fifth embodiment;

FIG. 11 is a relation curve between current and voltage (I-V) obtained by testing ohmic contact electrodes on both P-type and N-type layers of GaN-based LED in a sixth embodiment;

FIG. 12 is a schematic view showing the test results of thermal stability of different ohmic contact electrodes on both P-type and N-type layers of GaN-based LED on the first and second embodiments;

FIG. 13 is a schematic view showing the test results of thermal stability of different ohmic contact electrodes on both P-type and N-type layers of GaN-based LED on the third and fourth embodiments;

FIG. 14 is a schematic view showing the test results of thermal stability of different ohmic contact electrodes on both P-type and N-type layers of GaN-based LED on the fifth and sixth embodiments.

### DETAILED DESCRIPTION

While the claims are not limited to the illustrated embodiments, an appreciation of various aspects of the present invention is best gained through a discussion of various examples thereof. Referring now to the drawings, illustrative embodiments will be described in detail. Although the drawings represent the embodiments, the drawings are not necessarily to scale and certain features may be exaggerated to better illustrate and explain an innovative aspect of an embodiment. Further, the embodiments described herein are not intended to be exhaustive or otherwise limiting or restricting to the precise form and configuration shown in the drawings and disclosed in the following detailed description.

### First Embodiment

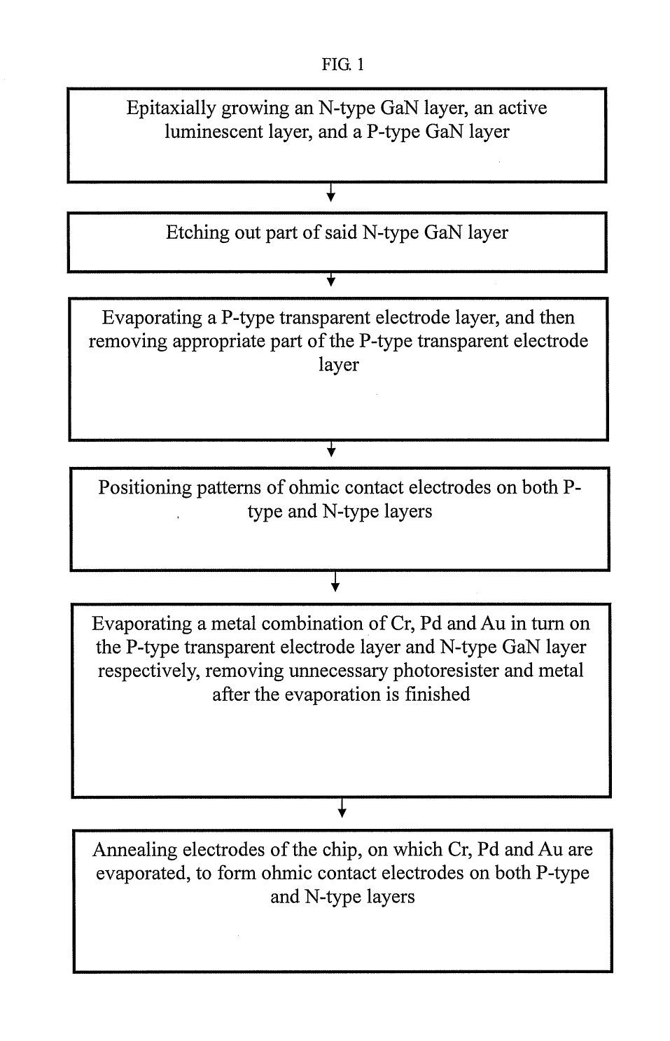

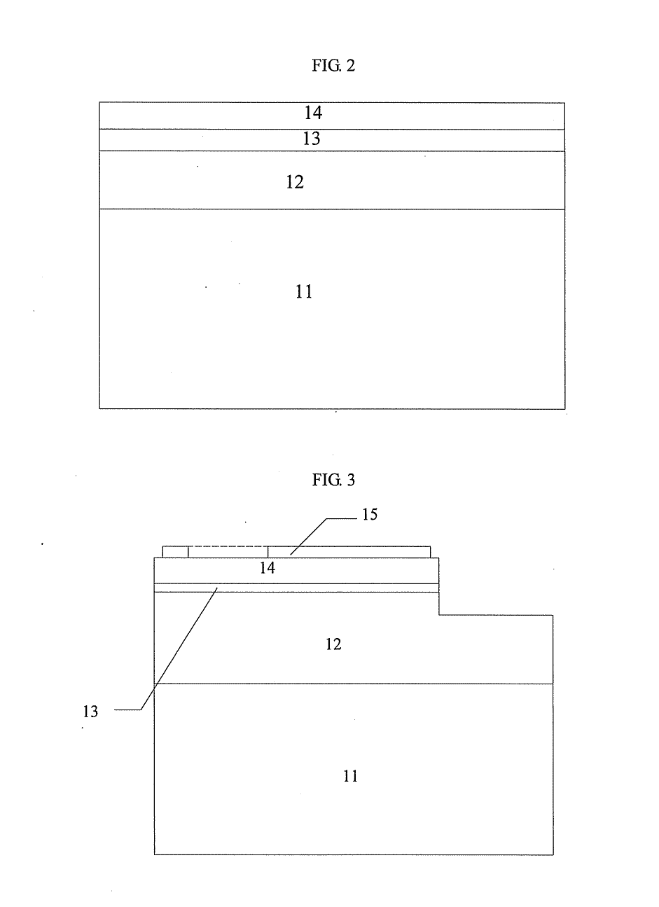

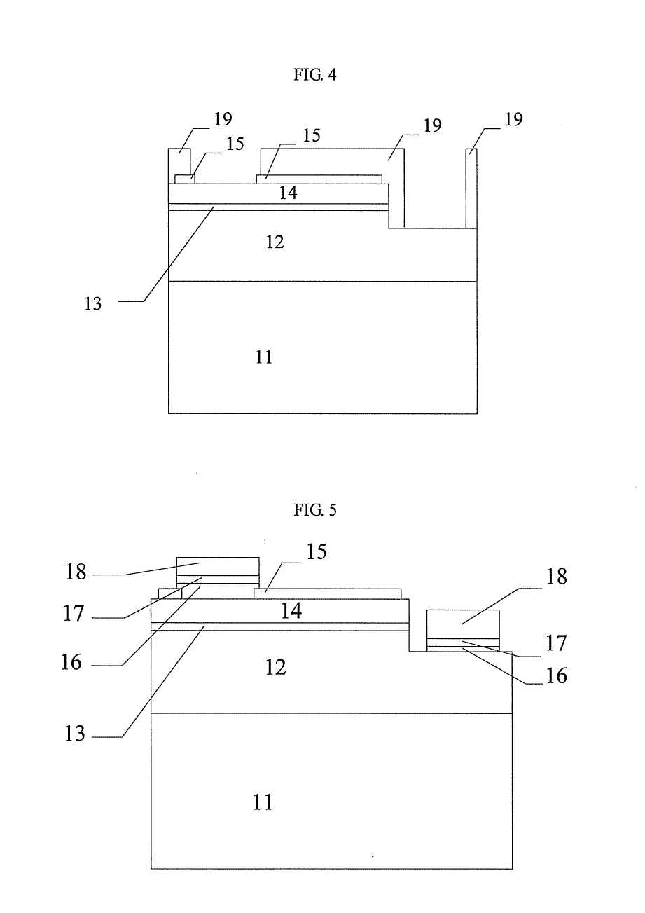

FIG. 1 is a fabrication flow chat of a set of ohmic contact electrodes on both P-type and N-type layers of a GaN-based LED according the present invention. FIG. 2 is a sectional view of the epitaxial structure of GaN-based LED chip on a sapphire substrate. FIG. 3 is a schematic view of etching out part of N-type layer on the epitaxial structure of chip and forming P-type transparent electrode layer. FIG. 4 is a schematic view showing positioning of ohmic contact electrodes on both P-type and N-type layers which are to be evaporated. FIG. 5 is a structure scheme of ohmic contact electrodes on both P-type and N-type layers of a GaN-based LED fabricated by using a metal combination of Cr/Pd/Au.

As shown in FIG. 1-FIG. 5, a method for fabricating set of ohmic contact electrodes on both P-type and N-type layers of GaN-based LED according to the present disclosure generally comprises the following steps:
(1) epitaxially growing an N-type GaN layer 12, an active luminescent layer 13, and a P-type GaN layer 14 on a sapphire substrate 11, as shown in FIG. 2;
(2) etching out part of the N-type GaN layer 12 with a plasma etcher;
(3) evaporating a P-type transparent electrode layer 15 on the surface of the P-type GaN layer 14 at a vacuum degree of 9.99×10⁻⁷ Torr, and then removing an appropriate part of P-type transparent electrode layer 15 by photolithography and etching to prepare for evaporating the ohmic contact electrode in the next step, as shown in FIG. 3;
(4) coating photoresister 19 on the surface of an epitaxial structure of the chip by high speed spin-coating, then baking the chip until it is semi-dry, and using photomasks of P-electrode and N-electrode as a mask to photolithograph and develop the P-type transparent electrode layer 15 and N-type GaN layer 12 on an aligner, thus positioning patterns of ohmic contact electrodes on the P-type and N-type layers respectively, as shown in FIG. 4;
(5) evaporating a metal combination of a Cr layer 16 500 Å thick, a Pd layer 17 1000 Å thick and an Au layer 18 20000 Å thick in turn on the P-type transparent electrode layer 15 and N-type GaN layer 12 respectively at a vacuum degree of 9.99×10⁻⁷ Torr by using an E-Beam & Thermal (electron beam evaporator), and then removing unnecessary photoresister 19 and metals by stripping after the evaporation is finished;
(6) annealing electrodes of the chip, on which Cr layer 16, Pd layer 17 and Au layer 18 are evaporated, for 20 minutes in nitrogen atmosphere at a temperature of 450 degrees in a tubular alloy furnace to form excellent ohmic contact electrodes on both P-type and N-type layers, as shown in FIG. 5.

### Second Embodiment

A method for fabricating a set of ohmic contact electrodes on both P-type and N-type layers of a GaN-based LED according to the present disclosure generally comprises the following steps:
(1) epitaxially growing an N-type GaN layer 12, an active luminescent layer 13, and a P-type GaN layer 14 on a sapphire substrate 11;
(2) etching out part of the N-type GaN layer 12 with a plasma etcher;
(3) evaporating a P-type transparent electrode layer 15 on the surface of the P-type GaN layer 14 at a vacuum degree of 9.99×10⁻⁷ Torr, and then removing an appropriate part of a P-type transparent electrode layer 15 by photolithography and etching to prepare for evaporating an ohmic contact electrode in the next step;
(4) coating photoresister 19 on the surface of an epitaxial structure of chip by high speed spin-coating, then baking it until it is semi-dry, and using photomasks of a P-electrode and an N-electrode as a mask to photolithograph and develop the P-type transparent electrode layer 15 and N-type GaN layer 12 on an aligner, thus positioning patterns of ohmic contact electrodes on the P-type and N-type layers respectively;
(5) evaporating a metal combination of a Cr layer 16 400 Å thick, a Pd layer 17 800 Å thick and an Au layer 18 15000 Å thick in turn on the P-type transparent electrode layer 15 and N-type GaN layer 12, respectively at a vacuum degree of 9.99×10⁻⁷ Torr by using an E-Beam & Thermal, and then removing unnecessary photoresister 19 and metals by stripping after the evaporation is finished; and
(6) annealing electrodes of the chip, on which Cr layer 16, Pd layer 17 and Au layer 18 are evaporated, for 15 minutes in a nitrogen atmosphere at a temperature of 400 degrees in a tubular alloy furnace to form excellent ohmic contact electrodes on both P-type and N-type layers.

### Third Embodiment

A method for fabricating a set of ohmic contact electrodes on both P-type and N-type layers of a GaN-based LED according to the present disclosure generally comprises the following steps:
(1) epitaxially growing an N-type GaN layer 12, an active luminescent layer 13, and a P-type GaN layer 14 on a sapphire substrate 11;
(2) etching out part of the N-type GaN layer 12 with a plasma etcher;
(3) evaporating a P-type transparent electrode layer 15 on the surface of the P-type GaN layer 14 at a vacuum degree of 9.99×10⁻⁷ Torr, and then removing appropriate part of P-type transparent electrode layer 15 by photolithography and etching to prepare for evaporating ohmic contact electrode in the next step;
(4) coating photoresister 19 on the surface of an epitaxial structure of chip by high speed spin-coating, then baking it until it is semi-dry, and using photomasks of P-electrode and N-electrode as mask to photolithograph and develop P-type transparent electrode layer 15 and N-type GaN layer 12 on an aligner, thus positioning patterns of ohmic contact electrodes on the P-type and N-type layers respectively;
(5) evaporating a metal combination of a Cr layer 16 50 Å thick, a Pd layer 17 300 Å thick and an Au layer 18 3000 Å thick in turn on the P-type transparent electrode layer 15 and N-type GaN layer 12 respectively at a vacuum degree of 9.99×10⁻⁷ Torr by using an E-Beam & Thermal, and then removing unnecessary photoresister 19 and metals by stripping after the evaporation is finished;
(6) annealing electrodes of the chip, on which Cr layer 16, Pd layer 17 and Au layer 18 are evaporated, for 5 minutes in nitrogen atmosphere at a temperature of 200 degrees in a tubular alloy furnace to form excellent ohmic contact electrodes on both P-type and N-type layers.

### Fourth Embodiment

A method for fabricating a set of ohmic contact electrodes on both P-type and N-type layers of GaN-based LED according to the present disclosure generally comprises the following steps:
(1) epitaxially growing an N-type GaN layer 12, an active luminescent layer 13, and a P-type GaN layer 14 on a sapphire substrate 11;
(2) etching out part of the N-type GaN layer 12 with a plasma etcher;
(3) evaporating a P-type transparent electrode layer 15 on the surface of the P-type GaN layer 14 at a vacuum degree of 9.99×10⁻⁷ Torr, and then removing an appropriate part of P-type transparent electrode layer 15 by photolithography and etching to prepare for evaporating ohmic contact electrode in the next step;
(4) coating photoresister 19 on the surface of epitaxial structure of chip by high speed spin-coating, then baking it until it is semi-dry, and using photomasks of P-electrode and N-electrode as mask to photolithograph and develop P-type transparent electrode layer 15 and N-type GaN layer 12 on an aligner, thus positioning patterns of ohmic contact electrodes on the P-type and N-type layers respectively;
(5) evaporating a metal combination of a Cr layer 16 100 Å thick, a Pd layer 17 500 Å thick and an Au layer 18 5000 Å thick in turn on the P-type transparent electrode layer 15 and N-type GaN layer 12 respectively at a vacuum degree of 9.99×10⁻⁷ Torr by using an E-Beam & Thermal, and then removing unnecessary photoresister 19 and metals by stripping after the evaporation is finished; and
(6) annealing electrodes of the chip, on which Cr layer 16, Pd layer 17 and Au layer 18 are evaporated, for 10 minutes in nitrogen atmosphere at the temperature of 250 degrees in a tubular alloy furnace to form excellent ohmic contact electrodes on both P-type and N-type layers.

### Fifth Embodiment

A method for fabricating a set of ohmic contact electrodes on both P-type and N-type layers of GaN-based LED according to the present disclosure generally comprises the following steps:
(1) epitaxially growing an N-type GaN layer 12, an active luminescent layer 13, and a P-type GaN layer 14 on a sapphire substrate 11;
(2) etching out part of said N-type GaN layer 12 with plasma etcher;
(3) evaporating a P-type transparent electrode layer 15 on the surface of the P-type GaN layer 14 at a vacuum degree of 9.99×10⁻⁷ Torr, and then removing an appropriate part of P-type transparent electrode layer 15 by photolithography and etching to prepare for evaporating ohmic contact electrode in the next step;
(4) coating photoresister 19 on the surface of epitaxial structure of chip by high speed spin-coating, then baking it until it is semi-dry, and using photomasks of P-electrode and N-electrode as a mask to photolithograph and develop P-type transparent electrode layer 15 and N-type GaN layer 12 on an aligner, thus positioning patterns of ohmic contact electrodes on the P-type and N-type layers respectively;
(5) evaporating a metal combination of a Cr layer 16 200 Å thick, a Pd layer 17 400 Å thick and an Au layer 18 10000 Å thick in turn on the P-type transparent electrode layer 15 and N-type GaN layer 12 respectively at a vacuum degree of 9.99×10⁻⁷ Torr by using an E-Beam & Thermal, and then removing unnecessary photoresister 19 and metals by stripping after the evaporation is finished; and
(6) annealing electrodes of the chip, on which Cr layer 16, Pd layer 17 and Au layer 18 are evaporated, for 15 minutes in nitrogen atmosphere at a temperature of 350□ in a tubular alloy furnace to form excellent ohmic contact electrodes on both P-type and N-type layers.

### Sixth Embodiment

A method for fabricating a set of ohmic contact electrodes on both P-type and N-type layers of GaN-based LED according to the present disclosure generally comprises the following steps:
(1) epitaxially growing an N-type GaN layer 12, an active luminescent layer 13, and a P-type GaN layer 14 on a sapphire substrate 11;
(2) etching out part of said N-type GaN layer 12 with a plasma etcher;
(3) evaporating a P-type transparent electrode layer 15 on the surface of the P-type GaN layer 14 at a vacuum degree of 9.99×10⁻⁷ Torr, and then removing an appropriate part of a P-type transparent electrode layer 15 by photolithography and etching to prepare for evaporating ohmic contact electrode in the next step;
(4) coating photoresister 19 on the surface of epitaxial structure of chip by high speed spin-coating, then baking it until it is semi-dry, and using photomasks of a P-electrode and N-electrode as a mask to photolithograph and develop P-type transparent electrode layer 15 and N-type GaN layer 12 on an aligner, thus positioning patterns of ohmic contact electrodes on the P-type and N-type layers respectively;
(5) evaporating a metal combination of a Cr layer 16 200 Å thick, a Pd layer 17 600 Å thick and an Au layer 18 10000 Å thick in turn on the P-type transparent electrode layer 15 and N-type GaN layer 12 respectively at a vacuum degree of 9.99×10⁻⁷ Torr by using E-Beam & Thermal, and then removing unnecessary photoresister 19 and metals by stripping after the evaporation is finished; and
(6) annealing electrodes of the chip, on which Cr layer 16, Pd layer 17 and Au layer 18 are evaporated, for 15 minutes in nitrogen atmosphere at the temperature of 300□ in a tubular alloy furnace to form excellent ohmic contact electrodes on both P-type and N-type layers.

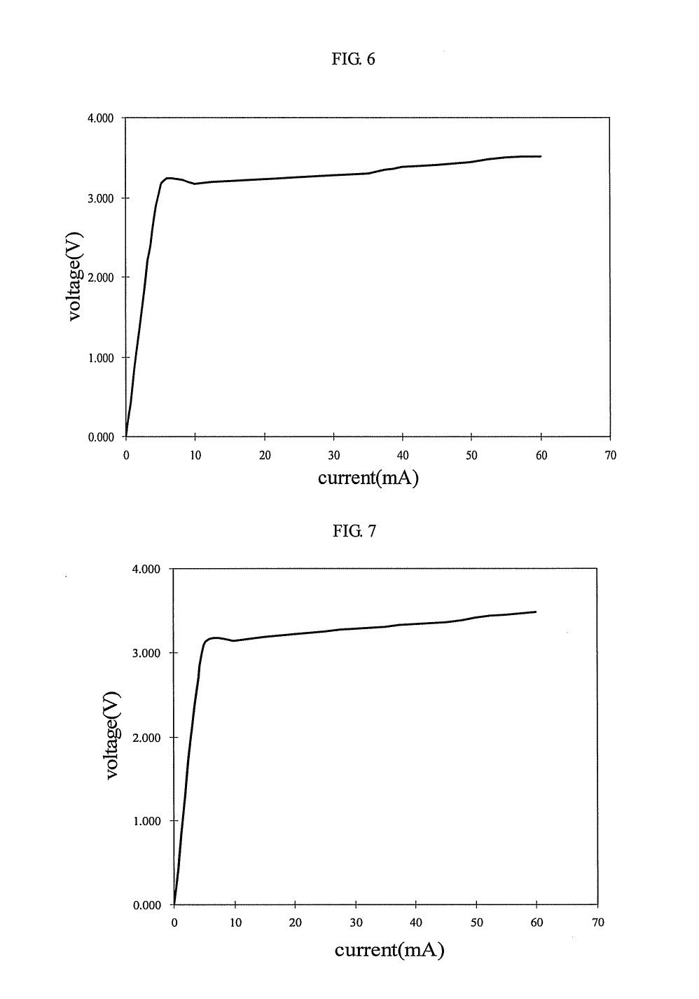

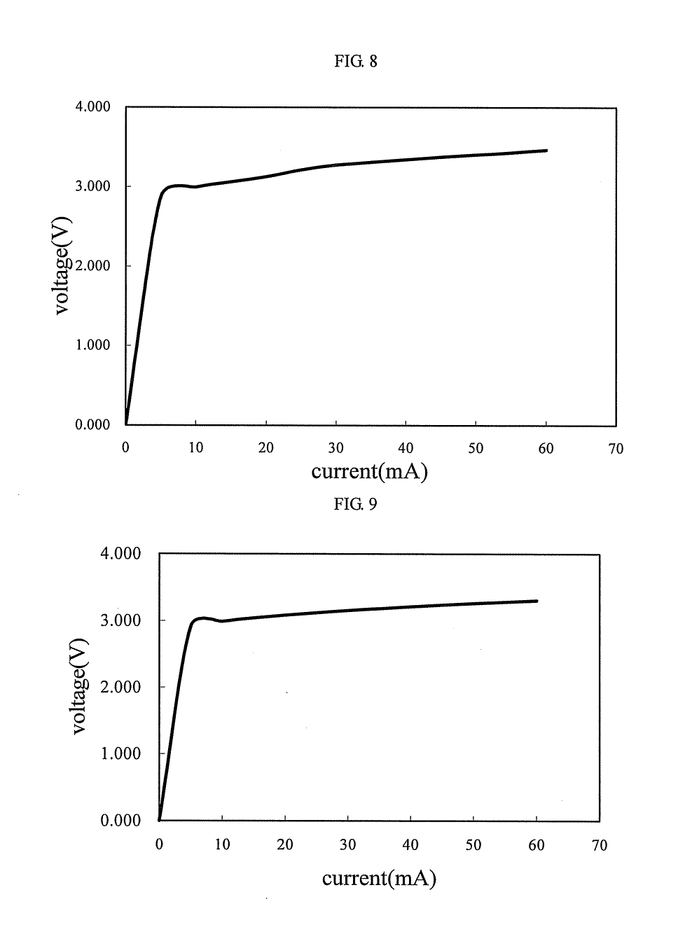

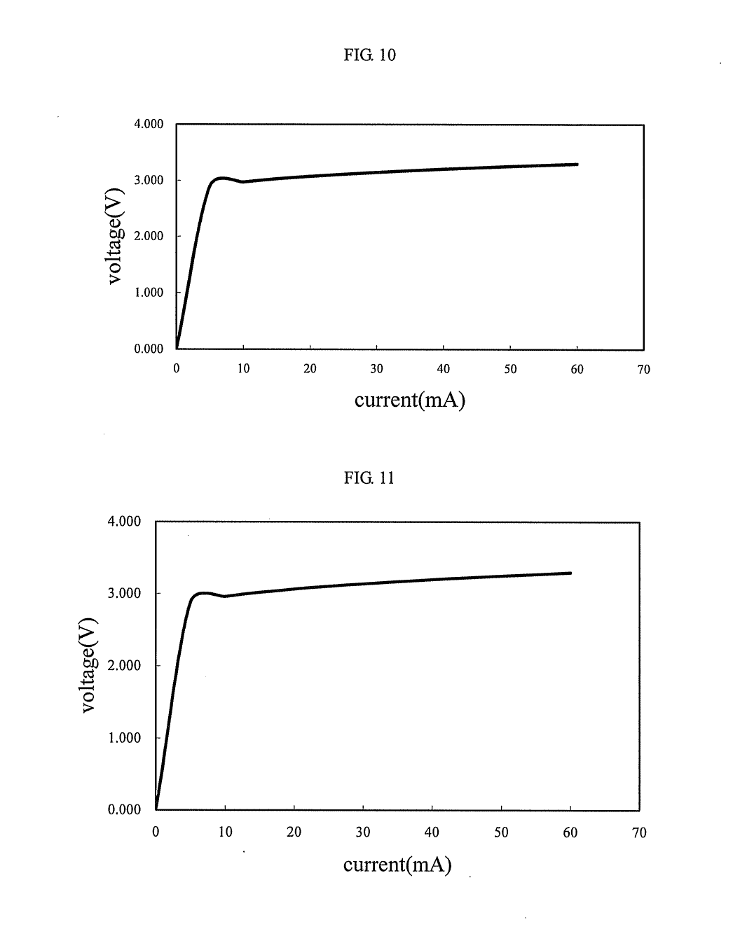

FIG. 6-FIG. 11 are relation curves between current and voltage (I-V) obtained by testing ohmic contact electrodes on both P-type and N-type layers of a GaN-based LED in the first, second, third, fourth, fifth and sixth embodiments respectively. As shown in FIG. 6 to FIG. 11, every one of the relations between current and voltage of ohmic contact electrodes in the first to sixth embodiments shows a linear one, exhibiting excellent ohmic contact characteristic. Among the embodiments, the ohmic contact characteristic of ohmic contact electrodes fabricated by Cr/Pd/Au (200/600/10000 Å) in the sixth embodiment is the best.

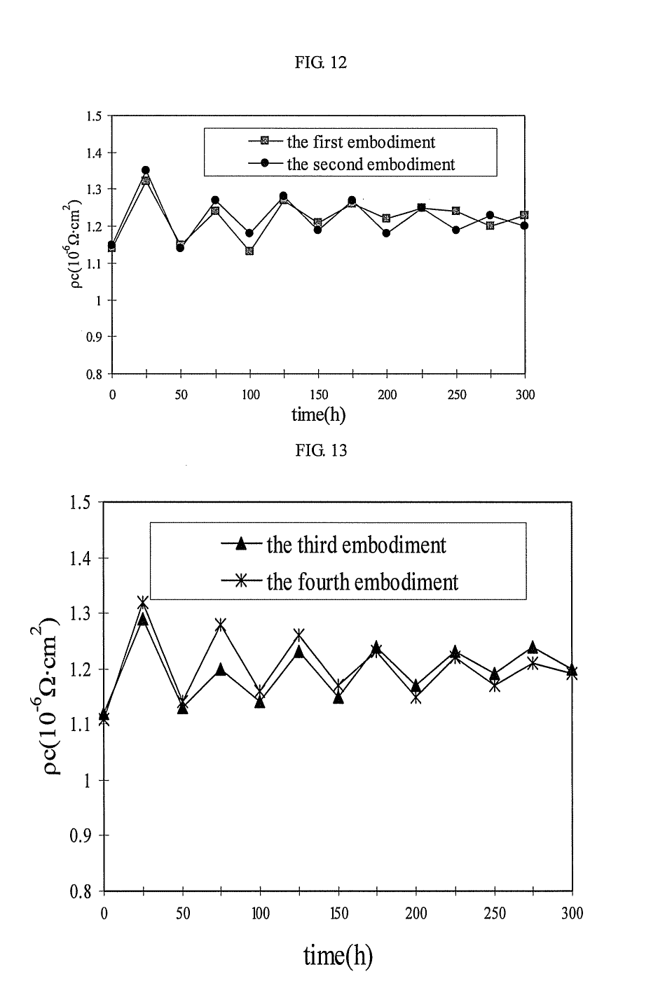

FIG. 12 is a schematic view showing the test results of thermal stability of different ohmic contact electrodes on both P-type and N-type layers of a GaN-based LED under a constant temperature of 85 degrees in the first and second embodiments.

FIG. 13 is a schematic view showing the test results of thermal stability of different ohmic contact electrodes on both P-type and N-type layers of a GaN-based LED under a constant temperature of 85 degrees in the third and fourth embodiments.

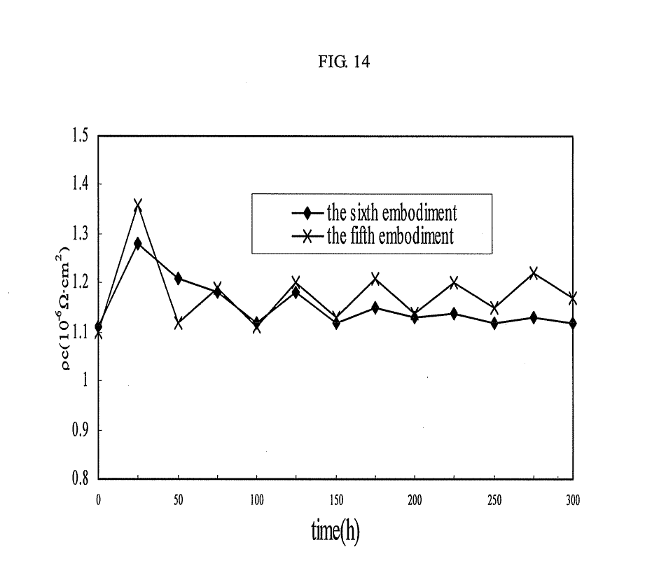

FIG. 14 is a schematic view showing the test results of thermal stability of different ohmic contact electrodes on both P-type and N-type layers of a GaN-based LED under a constant temperature of 85 degrees in the fifth and sixth embodiments.

As shown in FIG. 12-14, all specific contact resistivities ρ_{c} of ohmic contact electrodes in the first to sixth embodiments have little fluctuation with the increase of test time. All curves show no obvious upward trend or downward trend, which indicates that the thermal stability of ohmic contact electrode is better, thereby the reliability of the diode is improved. Among the embodiments, the thermal stability of ohmic contact electrodes fabricated by Cr/Pd/Au (200/600/10000 Å) in the sixth embodiment is the best.

By using the metal combination of Cr/Pd/Au as the material of the ohmic contact electrodes, the present disclosure increases the electron concentration on the surface of electrodes, obtains excellent ohmic contact characteristics, obtains better thermal stability and the electrode is not easy to be oxidized, thus improving the reliability of diode.

The foregoing description of various embodiments of the invention has been present for purpose of illustration and description. It is not intent to be exhaustive or to limit the invention to the precise embodiments disclosed. Numerous modifications or variations are possible in light of the above teachings. The embodiments discussed where chosen and described to provide the best illustration of the principles of the invention and its practical application to thereby enable one of ordinary skill in the art to utilize the invention in various embodiments and with various modifications as are suited to the particular use contemplated. All such modifications and variations are within the scope of the invention as determined by the appended claims when interpreted in accordance with the breadth to which they are fairly, legally, and equitably entitled.

What is claimed is:

1. A set of ohmic contact electrodes, comprising a set of ohmic contact electrodes positioned on both P-type and N-type layers of a GaN-Based light emitting diode (LED), wherein the material of said ohmic contact electrodes is a metal combination of Cr/Pd/Au; a first layer of ohmic contact electrode is evaporated on the P-type transparent electrode layer and the N—GaN layer is Cr, the second layer is Pd, and the third layer is Au; and a thickness of the Cr layer is equal to or thicker than 50 Å and equal to or thinner than 500 Å, a thickness of the Pd layer is equal to or thicker than 300 Å and equal to or thinner than 1000 Å, and a thickness of the Au layer is equal to or thicker than 3000 Å and equal to or thinner than 20000 Å.

2. The set of ohmic contact electrodes on both P-type and N-type layers of GaN-Based LED according to claim 1, wherein the thickness of said Cr layer is equal to or thicker than 100 Å and equal to or thinner than 200 Å, the thickness of said Pd layer is equal to or thicker than 400 Å and equal to or thinner than 600 Å, and the thickness of said Au layer is equal to or thicker than 5000 Å and equal to or thinner than 10000 Å.

3. The set of ohmic contact electrodes on both P-type and N-type layers of GaN-Based LED according to claim 1 or claim 2, wherein the thickness of said Cr layer is 200 Å, the thickness of said Pd layer is 600 Å, and the thickness of said Au layer is 10000 Å.

4. A method for fabricating the set of ohmic contact electrodes on both P-type and N-type layers of GaN-based LED comprising:
(1) epitaxially growing an N-type GaN layer, an active luminescent layer, and a P-type GaN layer on a sapphire substrate;
(2) etching out part of said N-type GaN layer;
(3) evaporating a P-type transparent electrode layer on a surface of the P-type GaN layer at a vacuum degree of less than 1×10⁻⁶ Torr, and then removing a predetermined amount of the P-type transparent electrode layer by photolithography and etching;
(4) photolithographing and developing the P-type transparent electrode layer and N-type GaN layer to position patterns of ohmic contact electrodes on the P-type and N-type layers respectively;
(5) evaporating a metal combination of Cr, Pd and Au in turn on the P-type transparent electrode layer and N-type GaN layer respectively at a vacuum degree of less than 1×10⁻⁶ Torr, and then removing unnecessary photoresister and metals after the evaporation is finished;
(6) annealing electrodes of the chip on which Cr, Pd and Au are evaporated, in nitrogen atmosphere for a time being equal to or longer than 5 minutes and equal to or shorter than 20 minutes at a temperature being equal to or higher than 200 degrees and equal to or lower than 450 degrees to form ohmic contact electrodes on both the P-type and N-type layers.

5. The method for fabricating the set of ohmic contact electrodes on both P-type and N-type layers of GaN-based LED according to claim 4, wherein the temperature in step (6) is equal to or higher than 250 degrees and equal to or lower than 350 degrees.

6. The method for fabricating the set of ohmic contact electrodes on both P-type and N-type layers of GaN-based LED according to claim 4, wherein the time in step (6) is equal to or longer than 10 minutes and equal to or shorter than 15 minutes.
